(19) United States
(12) Patent Application Publication
(10) Pub. No.: US 2025/0251659 A1
(43) Pub. Date: Aug. 7, 2025

(54) METHOD AND APPARATUS WITH AI MODEL FOR MASK IMAGE GENERATION

(71) Applicant: Samsung Electronics Co., Ltd., Suwon-si (KR)

(72) Inventors: Youngchul KWAK, Suwon-si (KR); Deokyoung KANG, Suwon-si (KR); Seong-Jin PARK, Suwon-si (KR); Serim RYOU, Suwon-si (KR); Seon Min RHEE, Suwon-si (KR)

(73) Assignee: Samsung Electronics Co., Ltd., Suwon-si (KR)

(21) Appl. No.: 19/043,953

(22) Filed: Feb. 3, 2025

(30) Foreign Application Priority Data
Feb. 2, 2024 (KR) 10-2024-0016942

(51) Int. Cl. G03F 1/36; G06N 3/0475; G06N 3/048

(52) U.S. Cl. CPC G03F 1/36; G06N 3/0475; G06N 3/048

(57) ABSTRACT

A method for generating a mask image may include generating the mask image from a target pattern by using a first artificial intelligence (AI) model, modifying the mask image by using an activation function, calculating a gradient of the activation function by using a gradient of a loss function determined based on a difference between the target pattern and a pattern predicted through an optical simulation the modified mask image performed by a second AI model, and updating the modified mask image based on the gradient of the activation function.

### CROSS-REFERENCE TO RELATED APPLICATION

This application claims priority to and the benefit of Korean Patent Application No. 10-2024-0016942 filed in the Korean Intellectual Property Office on Feb. 2, 2024, the entire contents of which is incorporated herein by reference.

### BACKGROUND

### 1. Field

The present disclosure relates to a method and apparatus for generating a mask image for mask fabrication by using an artificial intelligence model.

### 2. Related Art

To create a physical mask used in the manufacture of semiconductors, optical proximity correction (OPC) can be performed to modify the mask pattern in consideration of the diffraction of light. With general OPC, the shape of a mask may be updated as the mask is deformed according to rules determined by the user. In other words, a mask can be created by repeating modifications several times according to the pattern formed on the wafer.

This OPC method has the advantage of being advantageous in producing masks that meet the mask creation regulations, but has the disadvantage that its performance and speed are determined by the user's ability to choose optimal rule(s).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method for generating a mask image includes: generating the mask image from a target pattern by using a first artificial intelligence (AI) model inferring the mask image based on the target pattern; modifying the mask image by using an activation function; determining a gradient of the activation function by using a gradient of a loss function, the loss function determined based on a difference between the target pattern and a pattern predicted through an optical simulation on the modified mask image, the optical simulation performed by a second AI model; and updating the modified mask image based on the gradient of the activation function.

The determining a gradient of the activation function by using a gradient of a loss function determined based on a difference between the target pattern and a pattern predicted through an optical simulation on the modified mask image performed by a second AI model may include determining the gradient of the activation function based on pixel values of the modified mask image and the gradient of the loss function.

The determining the gradient of the activation function based on pixel values of the modified mask image and the gradient of the loss function may include determining the gradient of the activation function based on a size of the pixel value and the sign of the gradient of the loss function.

The determining the gradient of the activation function based on the size of the pixel value and the sign of the gradient of the loss function may include determining the gradient of the activation function as 1 in response to the pixel value being greater than 1 and the gradient of the loss function being a positive number or in response to the pixel value being smaller than 0 and the gradient of the loss function being a negative number.

The determining the gradient of the activation function based on the size of the pixel value and the sign of the gradient of the loss function may include determining the gradient of the activation function as 1 in response to the pixel value being greater than 0 and smaller than 1.

The determining the gradient of the activation function based on the size of the pixel value and the sign of the gradient of the loss function may include determining the gradient of the activation function as 0 in response to the pixel value being greater than 1+m and the gradient of the loss function being a negative number or in response to the pixel value being smaller than 0−m and the gradient of the loss function being a positive number, wherein the m is a real number greater than or equal to 0.

The determining the gradient of the activation function based on the size of the pixel value and the sign of the gradient of the loss function may include determining the gradient of the activation function as 1 in response to the pixel value being greater than 1+m and the gradient of the loss function being a positive number or in response to the pixel value being smaller than 0−m and the gradient of the loss function being a negative number, wherein the m is a real number greater than or equal to 0.

The determining the gradient of the activation function based on the size of the pixel value and the sign of the gradient of the loss function may include determining the gradient of the activation function as 1 in response to the pixel value being greater than 0−m and smaller than 1+m, wherein the m is a real number greater than or equal to 0.

In another general aspect, an apparatus for generating a mask image includes: a first artificial intelligence (AI) model configured to generate the mask image from a target pattern; and a mask modifier configured to modify the mask image by using an activation function, wherein the mask modifier is further configured to determine a gradient of the activation function by using a gradient of a loss function determined based on a difference between the target pattern and a pattern predicted through an optical simulation the modified mask image performed by a second AI model, and wherein the first AI model is updated based on the gradient of the activation function.

When determining the gradient of the activation function, the mask modifier may be configured to determine the gradient of the activation function based on a pixel value of the modified mask image and the sign of the gradient of the loss function.

When determining the gradient of the activation function based on the pixel value of the modified mask image and the sign of the gradient of the loss function, the mask modifier may be configured to determine the gradient of the activation function as 0 in response to the pixel value being greater than 1 and the gradient of the loss function being a negative number or in response to the pixel value being smaller than 0 and the gradient of the loss function being a positive number.

When determining the gradient of the activation function based on the pixel value of the modified mask image and the sign of the gradient of the loss function, the mask modifier may be configured to determine the gradient of the activation function as 1 in response to the pixel value being greater than 1 and the gradient of the loss function being a positive number or in response to the pixel value being smaller than 0 and the gradient of the loss function being a negative number.

When determining the gradient of the activation function based on the pixel value of the modified mask image and the sign of the gradient of the loss function, the mask modifier may be configured to determine the gradient of the activation function as 1 in response to the pixel value being greater than 0 and smaller than 1.

When determining the gradient of the activation function based on the pixel value of the modified mask image and the sign of the gradient of the loss function, the mask modifier may be configured to determine the gradient of the activation function as 0 in response to the pixel value being greater than 1+m and the gradient of the loss function being a negative number or in response to the pixel value being smaller than 0−m and the gradient of the loss function being a positive number, wherein the m is a real number greater than or equal to 0.

When determining the gradient of the activation function based on the pixel value of the modified mask image and the sign of the gradient of the loss function, the mask modifier may be configured to determine the gradient of the activation function as 1 in response to the pixel value being greater than 1+m and the gradient of the loss function being a positive number or in response to the pixel value being smaller than 0−m and the gradient of the loss function being a negative number, wherein the m is a real number greater than or equal to 0.

When determining the gradient of the activation function based on the pixel value of the modified mask image and the sign of the gradient of the loss function, the mask modifier may be configured to determine the gradient of the activation function as 1 in response to the pixel value being greater than 0−m and smaller than 1+m, wherein the m is a real number greater than or equal to 0.

In another general aspect, an apparatus for generating a mask image using an artificial intelligence (AI) model includes: one or more processors and a memory, wherein the memory stores instructions configured to cause the one or more processors to perform a process including: receiving a gradient of a loss function, the loss function determined based on a difference between a target pattern and a pattern predicted from an image generated by the AI model based on the target pattern; determining a gradient of an activation function based on a pixel value of the image and based on the gradient of the loss function; updating the AI model based on the gradient of the activation function; and generating the mask image using the updated AI model.

The determining the gradient of the activation function based on the pixel value of the image and the gradient of the loss function may include determining the gradient of the activation function as 0 in response to the pixel value being greater than 1 and the gradient of the loss function being a negative number or in response to the pixel value being smaller than 0 and the gradient of the loss function being a positive number.

The determining the gradient of the activation function based on the pixel value of the image and the gradient of the loss function may include determining the gradient of the activation function as 0 in response to the pixel value being greater than 1+m and the gradient of the loss function being a negative number in response to when the pixel value being smaller than 0-m and the gradient of the loss function being a positive number, wherein the m is a real number greater than or equal to 0.

The pattern may be predicted by optical simulation in response to an image generated by the AI model being modified based on the activation function.

### BRIEF DESCRIPTION OF THE DRAWINGS

FIG. 1 illustrates a photo process for manufacturing a semiconductor wafer according to one or more embodiments.

FIG. 2A illustrates a target pattern according to one or more embodiments.

FIG. 2B illustrates a mask image fabricated without OPC according to one or more embodiments and a pattern on a wafer surface.

FIG. 2C illustrates a mask image fabricated through OPC according to one or more embodiments and a pattern on a wafer surface.

FIG. 3 illustrates a computing apparatus configured to generate a mask image according to one or more embodiments.

FIG. 4 illustrates a method for generating a mask image according to one or more embodiments.

FIG. 5 illustrates a sigmoid function and clamp function according to one or more embodiments.

FIG. 6 illustrates a portion of a mask image updated by using a clamp function according to according to one or more embodiments.

FIG. 7 illustrates a portion of a mask image updated by using a gradient-variable clamp function according to one or more embodiments.

FIG. 8 illustrates a portion of a mask image updated by using a gradient-variable clamp function considering a margin according to one or more embodiments.

FIG. 9 illustrates a computing apparatus configured to generate a mask image according to one or more embodiments.

FIG. 10 illustrates a neural network according to one or more embodiments.

FIG. 11 illustrates a computing apparatus according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

The artificial intelligence models (AI models) described herein are machine learning models that learns at least one task and can be implemented as a computer program (instructions) executed by a processor. The task learned by the AI model may involve solving a problem through machine learning or a work to be performed through machine learning. AI models may be implemented as computer programs that run on computing devices, downloaded over a network, or sold in a product form. Alternatively, the AI model(s) may be connected to various devices through a network. Also, the AI model(s) may be interoperable with various devices through a network.

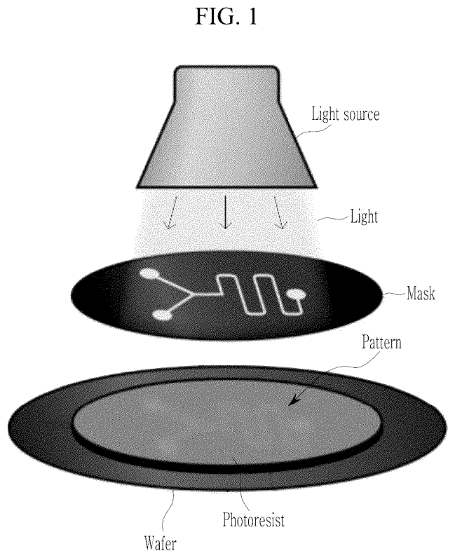

FIG. 1 illustrates a photo process for manufacturing a semiconductor wafer according to one or more embodiments.

To produce semiconductors (DRAM, flash memory, logic semiconductors, etc.), a processes may include, as non-limiting examples, a wafer manufacturing, an oxidation process, a photo process, an etching process, a deposition, an ion implanting, a metal wiring process, an electrical die sorting (EDS) process, and a packaging process. Referring to FIG. 1, in the photo process, light radiated from a light source passes through a cut-out pattern of a mask (with diffraction occurring). The pattern-passed and partly diffracted light is reaches the surface of a wafer coated with a photoresist, for example, and reaction between the light and the photoresist creates a desired circuit pattern on the wafer.

The pattern can be printed/formed on the wafer due to differences in (i) the properties of the photoresist in areas that receive the light that passes through the pattern of the mask and (ii) areas that do not. For example, when a positive photoresist is used, areas on the wafer that receive light are removed, and when a negative photoresist is used, the areas on the wafer that have not received light are removed.

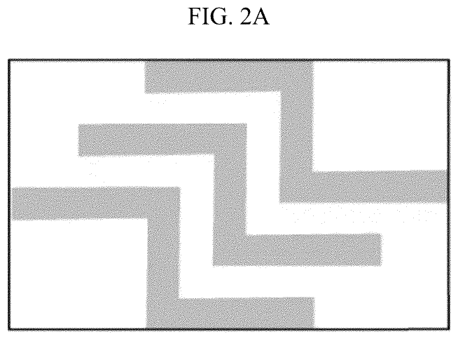

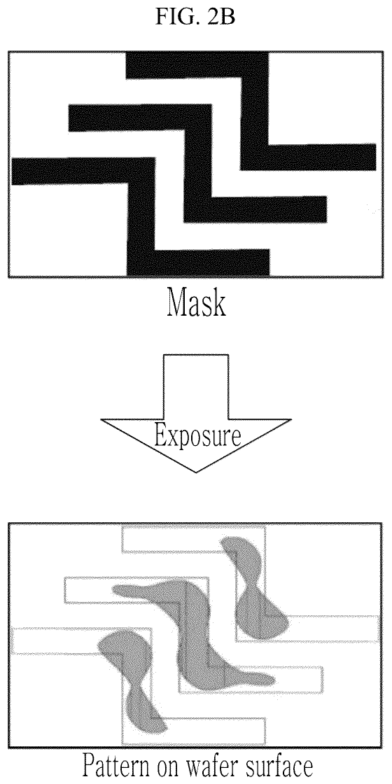

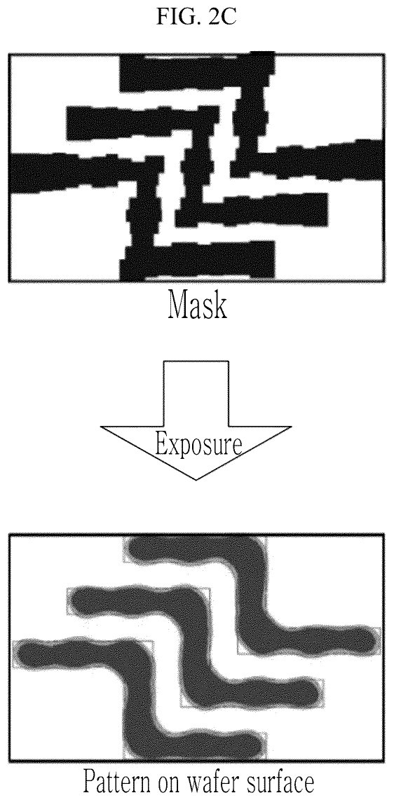

FIG. 2A illustrates a target pattern according to one or more embodiments. FIG. 2B illustrates a mask fabricated without an OPC process according to one or more embodiments and a pattern of light cast onto a wafer surface through the mask. FIG. 2C illustrates a mask fabricated through an OPC process according to one or more embodiments and a corresponding light pattern cast on a wafer surface through the mask.

Because light diffracts as it passes through a mask pattern, the cast pattern of light formed on the wafer surface will usually differ from the pattern printed on the mask. Referring to FIG. 2A and FIG. 2B, it may be seen that, when a mask having the same pattern as a target pattern (e.g., a desired wire pattern to be formed) shown in FIG. 2A is generated, the pattern formed on the wafer surface after the exposure differs significantly from the desired target pattern.

However, referring to FIG. 2A and FIG. 2C, in consideration of a diffraction effect (e.g., a degree of light diffraction), when a mask having a pattern that differs slightly from the target pattern (FIG. 2A) is generated, the corresponding pattern of light cast by the mask (and the formed pattern of wire on the wafer surface after the exposure) is a close approximation of the desired target pattern.

To form a desired target pattern on a wafer, an OPC-based process may be performed to modify the mask pattern in consideration of the diffraction of light.

According to some embodiments, an OPC-based process may be performed through machine learning. Machine learning-based OPC has the advantage of being able to create an optimized mask by training an AI model with an appropriate distribution of training data.

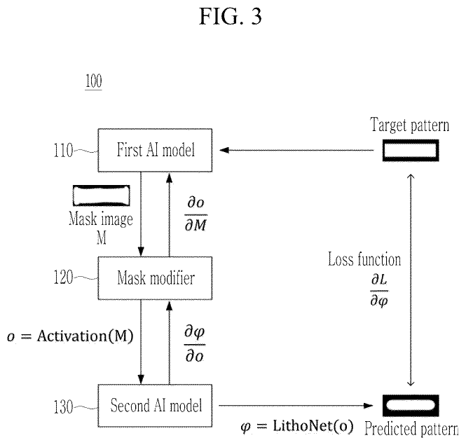

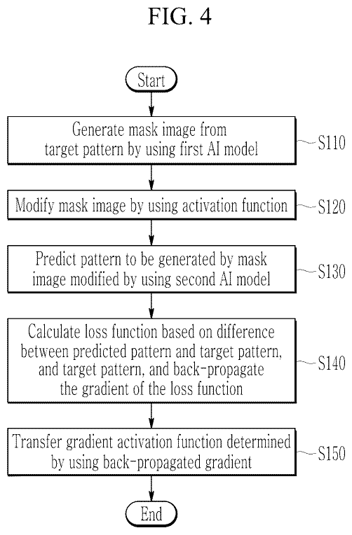

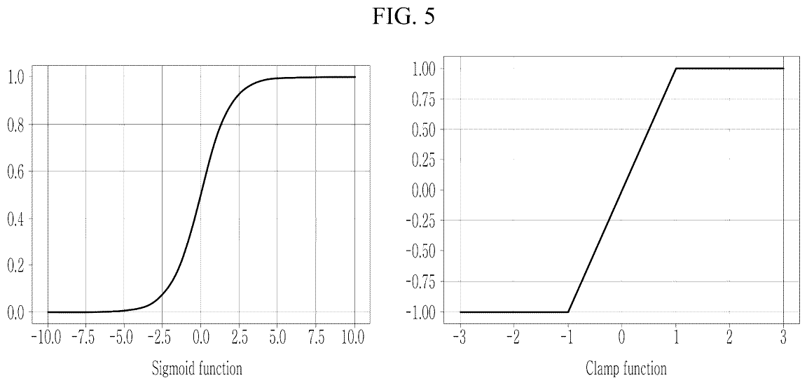

FIG. 3 illustrates a computing apparatus configured to generate a mask image according to one or more embodiments. FIG. 4 illustrates a method for generating a mask image according to one or more embodiments. FIG. 5 illustrates a sigmoid function and clamp function according to one or more embodiments.

Referring to FIG. 3, an apparatus 100 for generating a mask image according to one or more embodiments may include a first AI model 110, a mask modifier 120 (e.g., a unit of executable code/instructions), and a second AI model 130. The first AI model 110 may be referred to as an OPC network (OPCNet), and the second AI model 130 may be referred to as a lithography simulation network (LithoNet).

Regarding the first AI model 110 (e.g., an OPCNet, or “OPC neural network”), the model may be a neural network with an architecture configured to perform OPC, which, as noted above, is a technique used to optimize the design of photolithography masks by compensating for diffraction effects during the image transfer process, thus improving the accuracy of printed patterns on a wafer. The OPCNet learns the relationship between the target pattern and the corresponding mask adjustments able to achieve it, which significantly speeds up the OPC process relative to traditional algorithmic approaches. Convolutional neural networks (CNNs) may be used. Training data may be a large dataset of simulated or actual lithography results. An input training sample may be an original mask pattern (having an associated ground truth printed/cast pattern), and the inferred output may be the corresponding predicted optimal printed/cast pattern; the network may learn the difference between the inferred printed/cast pattern and the ground truth printed/cast pattern.

In some embodiments, the first AI model 110 may generate/infer a mask image configured to form a given target cast/printed pattern inputted to the first AI model 110. The second AI model 130 may be configured to predict a cast/printed pattern (as would be formed on a wafer) by performing optical simulation on a mask image inputted to the second AI model 130 (e.g., the mask image generated by the first AI model 110).

Referring to FIG. 4, at step S110, the first AI model 110 may receive a target pattern as an input and based thereon generate (infer) a mask image configured to form nearly the same pattern as the target pattern if applied to a wafer.

In some embodiments, the first AI model 110 may be trained to generate a mask image such that a corresponding physical mask is capable of forming, on a wafer, nearly the same pattern as a training pattern inputted to the first AI model 110, and the training may be done by using various training patterns, for example, training samples, where each training sample is a target pattern paired with a corresponding ground truth mask image. After such training, the trained first AI model 110 may generate, in an inference step, mask images capable of forming nearly the same respective patterns as corresponding target patterns inputted to the trained first AI model 110.

Referring to FIG. 4, at step S120, the mask modifier 120 may modify the mask image generated by the first AI model 110 generated at step S110 by using an activation function.

In some embodiments, use of the mask modifier 120 may improve complexity of the first AI model 110 and the second AI model 130, or, to improve performance of the models by limiting the ranges of their output values, may vary their activation functions.

Referring to FIG. 4, at step S130, the second AI model 130 may predict a pattern that would be formed on a wafer by performing optical simulation (e.g., simulating diffraction) on the mask image as modified by the mask modifier 120. Then, at step S140, a loss function between the target pattern and the pattern predicted from the optical simulation of the mask image modified by the mask modifier 120 may be determined, and a gradient of the loss function may be back-propagated to the first AI model 110.

When the first AI model 110 is trained by using various training patterns as mentioned above, due to a difference between the distribution of training data and the distribution of test data, an error may occur. That is, the data used to train the first AI model 110 may not be sufficient to train the first AI model 110 for different patterns that end up being used for test or production. To improve performance of the mask image generated by the first AI model 110 by minimizing such an error, the update on the first AI model 110 may be performed during the inference process. In some embodiments, the entire network may be updated based on the gradient of the loss function (the loss function being based on the second AI model 130); if the inference process is performed again with respect to the target pattern the new mask image generated by the updated first AI model 110 may form a pattern further closer to the original target pattern.

Referring to FIG. 4, at step S150, the mask modifier 120 according to one or more embodiments may propagate the gradient of the activation function determined by using the gradient back-propagated from the second AI model 130 to the first AI model 110.

The value of each pixel of the mask image generated by the apparatus 100 may be limited to between 0 to 1. For example, pixels with a value of 0 may represent no-pattern (e.g., representing a solid part of a physical mask) and 1 may represent a pixel portion with a pattern (e.g., representing an open part of a physical mask). Therefore, the activation function (see FIG. 5) (e.g., a sigmoid function) that outputs a value between 0 and 1 or a clamp function that outputs a value between −1 and 1, may be efficient to limit the range of values outputted by the first AI model 110 and the second AI model 130 during the network update process.

Additionally, even in the image update process, the activation function may be used to limit the range of the updated image based on a back-propagation of the first AI model 110 and the second AI model 130. The sigmoid function or clamp function thus not back-propagate for values below 0 and above 1.

A clamp function and a gradient of the clamp function may be implemented code analogous to the functions shown in Equation 1 below.

$$Clamp ( x ) = \{ \begin{matrix}0 & if x < 1 \\ x & if 0 \leq x \leq 1 \\ 1 & if x > 1\end{matrix} \qquad Equation 1$$

$$\frac{\partial Clamp ( x )}{\partial x} = \{ \begin{matrix}1 , & if 0 \leq x \leq 1 \\ 0 , & elsewhere\end{matrix}$$

When most of the pixel values of the mask image are 0 or 1, the gradient of the clamp function to be back-propagated becomes 0, so most of the mask image is not updated. At this time, if only a portion of the mask image is updated, spatial information may be lost.

For example, when the value of the pixel prior to applying the clamp function is 0 or −1, the mask modifier 120 may output 0 after applying the clamp function. However, the pixel having the value −1 may not be updated, so spatial information is partially lost. In particular, when the output values of the AI model are all 0 or less or 1 or more, the update may not proceed at all.

To solve the above problem, a DiffClamp function may be used, which back-propagates the clamp function with all gradients set to 1. The DiffClamp function may be implemented with code/instructions analogous to the function shown in Equation 2 below.

$$DiffC lamp ( x ) = \{ \begin{matrix}0 & if x < 0 \\ x & if 0 \leq x \leq 1 \\ 1 & if x > 1\end{matrix} \qquad Equation 2$$

$$\frac{\partial DiffClamp ( x )}{\partial x} = 1$$

When a DiffClamp function such as of Equation 2 is used, the gradient to be propagated is fixed to 1 and all areas of the mask image can be updated. However, when the gradient of the loss function based on the second AI model 130 (LithoNet) is propagated and the first AI model 110 (OPCNet) is updated through the propagated gradient of the loss function, the output of the network may diverge. Even when the mask image is updated based on the gradient of the loss function propagated from the second AI model 130, the same problem as in the update of the first AI model 110 may occur.

In some embodiments, the gradient of a mask image M fed back from the loss function may be implemented with code/instructions configured is indicated by Equation 3 below using the chain rule.

$$\frac{\partial L}{\partial M} = \frac{\partial o}{\partial M} \cdot \frac{\partial φ}{\partial o} \cdot \frac{\partial L}{\partial φ} = 1 \cdot \frac{\partial φ}{\partial o} \cdot \frac{\partial L}{\partial φ} = \frac{\partial L}{\partial o} \qquad Equation 3$$

In Equation 3, L represents a loss function for updating the network of the apparatus 100, φ is an output value of the second AI model 130, and o is n output value of a mask modifier 130. Referring to Equation 3, the gradient of the loss function ∂L/∂M transferred to the mask image M is the same as the gradient of the loss function ∂L/∂o propagated from the second AI model 130.

Meanwhile, when the DiffClamp function, which is the gradient-fixed clamp function, is used, the pixel value x of the mask image may be updated as follows. For example, when ∂L/∂o is smaller than 0 and DiffClamp(x) is

$$1 ( \frac{\partial L}{\partial o} < 0$$

and DiffClamp(x)=1), x may be updated to increase. At this time, because the output of the DiffClamp function DiffClamp(x) is limited to 1, the output does not increase but only x is continuously updated, such that the entire network may diverge. On the other hand, when ∂L/∂o is greater than 0 and DiffClamp(x) is 0, although the output of DiffClamp(x) is limited to 0, x is updated to be smaller, and in this case also, the entire network may diverge. To solve such a problem, the mask modifier 120 according to one or more embodiments may induce convergence of the network by using the activation function that is capable of selectively varying the gradient.

The mask modifier 120 according to one or more embodiments may determine a magnitude of the gradient to be propagated to the first AI model 110 according to the pixel value of the mask image and a magnitude of the gradient propagated from the second AI model 130, by using the gradient-variable clamp function (DiffClampClip) as the activation function.

Code or instructions analogous to Equation 4 below may implement the gradient-variable clamp function used by the mask modifier 120.

$$DiffC lampClip ( x ) = \{ \begin{matrix}0 & if x < 0 \\ x & if 0 \leq x \leq 1 \\ 1 & if x > 1\end{matrix} \qquad Equation 4$$

$$\frac{\partial DiffClampClip ( x )}{\partial x} = \{ \begin{matrix}0 , & if ( x > 1 and \frac{\partial L}{\partial o} < 0 ) or ( x < 0 and \frac{\partial L}{\partial o} > 0 ) \\ 1 , & elsewhere .\end{matrix}$$

Referring to Equation 4, when (i) the pixel value x of the mask image is greater than 1 and the propagated gradient ∂L/∂o as is a negative number or (ii) when the pixel value x of the mask image is smaller than 0 and the propagated gradient ∂L/∂o is a positive number, the gradient to be propagated to the first AI model 110 may become 0. As with the clamp function, the gradient of 1 may be propagated to the first AI model 110 when the pixel value x of the mask image is a value between 0 and 1. That is, the mask modifier 120 according to one or more embodiments may limit the gradient in the increasing direction when the pixel value of the mask image exceeds 1 and limit the gradient in the decreasing direction when the pixel value of the mask image is less than 0, so the network may converge.

The mask modifier 120 according to one or more embodiments may determine the magnitude of the gradient to be propagated to the first AI model 110 according to the pixel value of the mask image and the magnitude of the gradient propagated from the second AI model 130, by using the gradient-variable clamp function (DiffClampClip^{M}) as the activation function having considered a margin.

Code or instructions analogous to Equation 5 below may be used to implement the gradient of the gradient-variable clamp function having considered the margin used by the mask modifier 120.

$$\frac{\partial {DiffClampClip}^{M} ( x )}{\partial x} = \{ \begin{matrix}0 , & if ( x > 1 + m and \frac{\partial L}{\partial o} < 0 ) or ( x < 0 - m and \frac{\partial L}{\partial o} > 0 ) \\ 1 , & elsewhere .\end{matrix} \qquad Equation 5$$

Referring to Equation 5, when (i) the pixel value X of the mask image is greater than 1+m and the propagated gradient ∂L/∂o is a negative number, or when (ii) the pixel value x of the mask image is smaller than 0−m and the propagated gradient ∂L/∂o is a positive number, the gradient to be propagated to the first AI model 110 may become 0. Here, M is a real number greater than or equal to 0. The mask modifier 120 according to another embodiment may update the gradient to 1, even for pixel values close to 0 and 1, by considering the margin m to the gradient-variable clamp function of Equation 4, and accordingly, representation capability with respect to 0 and 1 of the mask image may be improved.

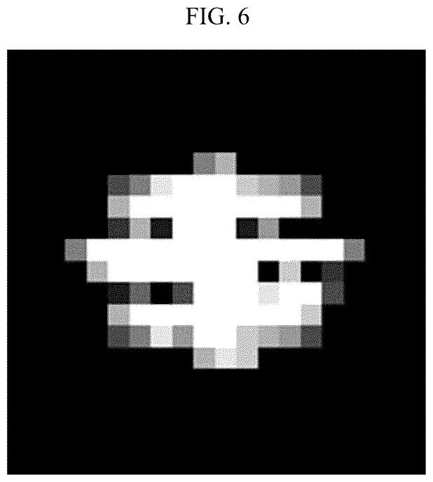

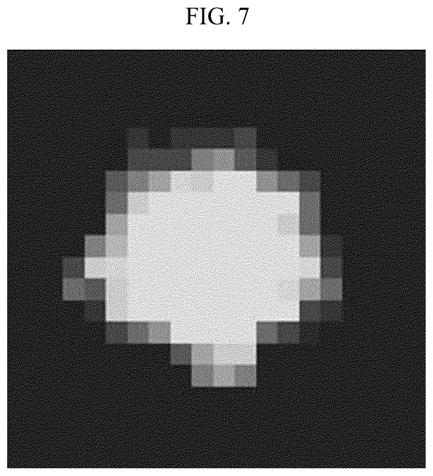

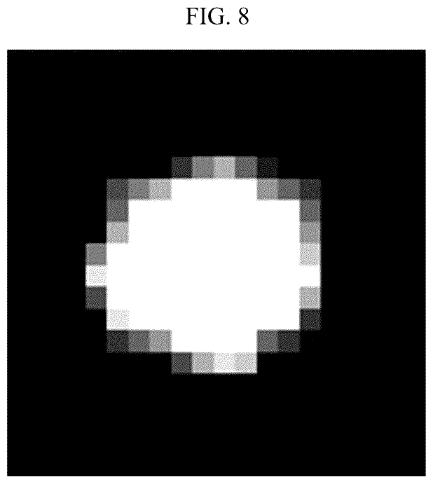

FIG. 6 illustrates a portion of a mask image updated by using the clamp function according to according to one or more embodiments. FIG. 7 illustrates a portion of a mask image updated by using the gradient-variable clamp function according to one or more embodiments. FIG. 8 illustrates a portion of a mask image updated by using the gradient-variable clamp function according to one or more embodiments.

Referring to FIG. 6, when the clamp function is used for update of the network, spatial information is lost and the boundary line is not smooth but irregular. It is difficult to produce a mask from such a mask image.

On the other hand, referring to FIG. 7, the gradient-variable clamp function according to one or more embodiments may be used for update of the network, and thereby a mask image having a smooth boundary line may be generated. However, the mask image updated by the gradient-variable clamp function may not accurately represent 0 and 1, and therefore, white and black are somewhat unclear and the image is blurred.

Referring to FIG. 8, it may be seen that the gradient-variable clamp function having considered the margin according to one or more embodiments is used for the update of the network, and accordingly, a mask image having a smooth boundary line and having an improved representation capability of 0 and 1 compared to FIG. 7 may be generated.

Table 1 below represents simulation results of mask images updated by respective activation functions. Table 1 shows the root mean square error (RMSE) of the critical dimension between the target pattern and the pattern predicted from the mask image as a cal/val (calibration/validation) value. In Table 1, the smaller the value, the better the performance, and therefore, it may be seen that the performance is better in the case that the gradient-variable clamp function and the gradient-variable clamp function having considered the margin are used, compared to the case that the plain clamp function is used.

TABLE 1

| | Clamp | DiffClampClip | M DiffClampClip^{M} |
|---|---|---|---|
| CD RMSE | 0.805/0.808 | 0.683/0.680 | 0.654/0.648 |
| (Cal/Val) | | | |

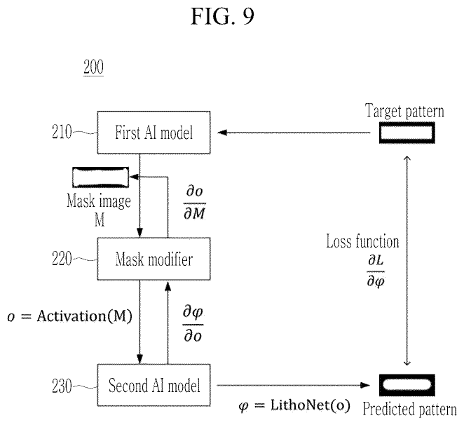

FIG. 9 illustrates a computing apparatus configured to generate a mask image according to one or more embodiments.

Referring to FIG. 9, a computing apparatus 200 according to one or more embodiments may include a first AI model 210, a mask modifier 220, and a second AI model 230. In some embodiments, the first AI model 210, the mask modifier 220, and the second AI model 230 of the generating apparatus 200 may perform the steps of S110 to S140 of FIG. 4, the same as the apparatus 100 for generating a mask image of FIG. 3.

According to one or more embodiments, the first AI model 210 may generate a mask image for forming the target pattern (as if on a wafer), and the mask image may be generated from the inputting of the target pattern. The mask modifier 220 may modify the mask image generated by the first AI model 210 by using the activation function. The second AI model 230 may perform optical simulation on the mask image as modified by the mask modifier 220 to predict a pattern to be formed (as if on a wafer). A loss function between the target pattern and the pattern predicted from the simulation result of the modified mask image may be calculated, and a gradient of the calculated loss function may be back-propagated from the second AI model 230 to the first AI model 210.

The mask modifier 220 according to one or more embodiments may update the mask image (the previously modified version of the mask image) used for optical simulation by using the gradient back-propagated from the activation function and the second AI model 230. Since the mask modifier 220 can update, by using the gradient back-propagated from the second AI model 230, the modified mask image that is modified before the optical simulation, the cost and time consumed for the update of the first AI model 210 may be reduced.

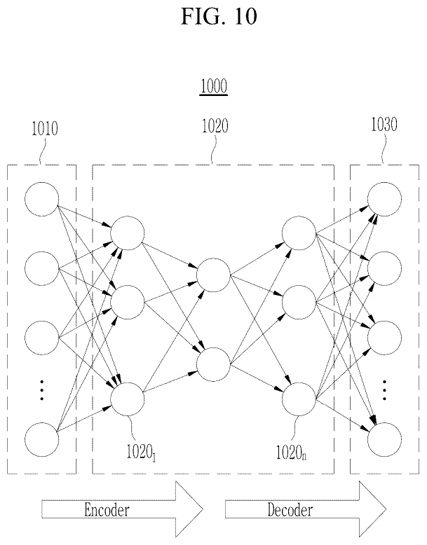

FIG. 10 illustrates a neural network model according to one or more embodiments. The neural network model in FIG. 10 shows basic features of the AI models mentioned above, albeit with possible architectural differences.

Referring to FIG. 10, the first AI model and/or the second AI model may have a neural network structure including an input layer 1010, a hidden layer portion 1020, and an output layer 1030. The neural network 1000 may have an encoder-decoder structure, and may constitute a portion and/or all of the generative AI model described above.

The input layer 1010, the hidden layer portion 1020, and the output layer 1030 may each include a respective set of nodes, and the strengths of connections between nodes may be represented as weights (connection weights). The network updating described above may update weights, for example. The nodes included in the input layer 1010, the hidden layer portion 1020, and the output layer 1030 may be connected to each other with a fully connected type of architecture, as a non-limiting example. In some implementations, the first and/or second AI models may be or may include a convolutional neural network.

The number of parameters (the weights and biases) may be equal to the number of connections within the neural network 1000. The input layer 1010 may include an input nodes (x₁ to xᵢ), and the number of input nodes (x₁ to xᵢ) may correspond to the number of independent variables of input data.

For training the neural network 1000 (e.g., first and/or second AI model), a data set may be input to the input layer 1010. When a mask image of an inference target is input to the input layer 1010 of the trained AI model, a corrected mask image may be output as the inference result from the output layer 1030 of the trained neural network 1000.

The hidden layer portion 1020 may be positioned between the input layer 1010 and the output layer 1030, and may include hidden layer(s) 1020₁ to 1020ₙ. The output layer 1030 may include at least one output node. An activation function may be used in the hidden layer portion 1020 and output layer 1030 to determine node outputs/activations.

In some embodiments, the neural network model 1000 may be learned by updating the weights and/or parameters of a hidden node included in the hidden layer portion 1020.

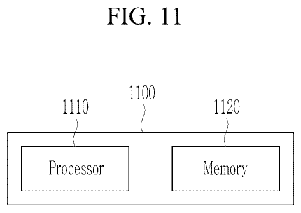

FIG. 11 illustrates a computing apparatus according to one or more embodiments. The mask generation apparatus may be implemented as a computer system, for example, as a computer-readable medium (but not a signal per se).

Referring to FIG. 11, the computing apparatus 1100 includes at least one processor 1110 and a memory 1120. The memory 1120 may be connected to the processor 1110 and may store instructions causing the the processor 1110 to perform a plurality of steps or at least one program described above.

The processor 1110 may implement the functions, processes, and methods described herein. An operation of the computing apparatus 1100 may be implemented by the processor 1110. The processor 1110 may be at least one of a GPU, a CPU, an NPU, an FPGA, a DSP, or the like. In practice the processor 1110, may be one or more processors of one or more types. When the operation of the computing apparatus 1100 is implemented by multiple processors, work may be divided according to the load among the processors. For example, when one processor is a CPU, another processor may be any of a GPU, NPU, FPGA, or DSP.

In the embodiments of the present disclosure, the at least one memory 1120 may be positioned internally or externally to the processor and the memory may be connected to the processor via a variety of known means. The memory 1120 is a type of storage medium that may be volatile or non-volatile. For example, the memory 1120 may include a read-only memory (ROM) or a random access memory (RAM).

In another way, some functions (e.g., training an AI or inference by an AI model) may be provided by a neuromorphic chip including neurons, synapses, and inter-neuron connection modules. The neuromorphic chip is a computer device simulating biological neural system structures, and may perform neural network operations.

Although implied above, an image mask generated by any of the techniques described above can be used to readily form a photolithography mask that can be used for producing semiconductor products, e.g., wafers or the like.

Embodiments and examples described herein may also be implemented through a program (code/instructions) that realizes a function corresponding to the configuration of embodiments or a recording medium in which the program is recorded. A computer-readable recording medium may include a hardware device configured to store and execute program instructions. For example, the computer-readable recording medium can be magnetic media such as hard disks, floppy disks, and magnetic tape, optical media such as CD-ROMs and DVDs, magneto-optical media such as floptical disks, ROM, RAM, flash memory, etc. Program instructions may include machine language code, such as that produced by a compiler, as well as high-level language code that can be executed by a computer through an interpreter, etc.

The computing apparatuses, the electronic devices, the processors, the memories, the image sensors, the displays, the information output system and hardware, the storage devices, and other apparatuses, devices, units, modules, and components described herein with respect to FIGS. 1-11 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-11 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method for generating a mask image, the method comprising:
generating the mask image from a target pattern by a first artificial intelligence (AI) model inferring the mask image based on the target pattern;
modifying the mask image by using an activation function;
determining a gradient of the activation function by using a gradient of a loss function, the loss function determined based on a difference between the target pattern and a pattern predicted through an optical simulation on the modified mask image, the optical simulation performed by a second AI model; and
updating the modified mask image based on the gradient of the activation function.

2. The method of claim 1, wherein the gradient of the activation function is determined based on pixel values of the modified mask image and the gradient of the loss function.

3. The method of claim 2, wherein the gradient of the activation function is determined based on a size of the pixel value and the sign of the gradient of the loss function.

4. The method of claim 3, wherein
the determining determining the gradient of the activation function based on the size of the pixel value and the sign of the gradient of the loss function comprises
determining the gradient of the activation function as 1 in response to the pixel value being greater than 1 and the gradient of the loss function being a positive number or in response to the pixel value being smaller than 0 and the gradient of the loss function being a negative number.

5. The method of claim 3, wherein the determining the gradient of the activation function based on the size of the pixel value and the sign of the gradient of the loss function comprises
determining the gradient of the activation function as 1 in response to the pixel value being greater than 0 and smaller than 1.

6. The method of claim 3, wherein the determining the gradient of the activation function based on the size of the pixel value and the sign of the gradient of the loss function comprises
determining the gradient of the activation function as 0 in response to the pixel value being greater than 1+m and the gradient of the loss function being a negative number or in response to the pixel value being smaller than 0−m and the gradient of the loss function being a positive number,
wherein the m is a real number greater than or equal to 0.

7. The method of claim 3, wherein the determining the gradient of the activation function based on the size of the pixel value and the sign of the gradient of the loss function comprises
determining the gradient of the activation function as 1 in response to the pixel value being greater than 1+m and the gradient of the loss function being a positive number or in response to the pixel value being smaller than 0−m and the gradient of the loss function being a negative number,
wherein the m is a real number greater than or equal to 0.

8. The method of claim 3, wherein the determining the gradient of the activation function based on the size of the pixel value and the sign of the gradient of the loss function comprises
determining the gradient of the activation function as 1 in response to the pixel value being greater than 0−m and smaller than 1+m,
wherein the m is a real number greater than or equal to 0.

9. An apparatus for generating a mask image, the apparatus comprising:
a first artificial intelligence (AI) model configured to generate the mask image from a target pattern;
wherein the mask image is modified by using an activation function,
wherein a gradient of the activation function is determined by using a gradient of a loss function determined based on a difference between the target pattern and a pattern predicted through an optical simulation the modified mask image, the optical simulation performed by a second AI model, and
wherein the first AI model is updated based on the gradient of the activation function.

10. The apparatus of claim 9, the determining the gradient of the activation function is based on a pixel value of the modified mask image and the sign of the gradient of the loss function.

11. The apparatus of claim 10, the determining the gradient of the activation function based on the pixel value of the modified mask image and the sign of the gradient of the loss function comprises determining the gradient of the activation function as 0 in response to the pixel value being greater than 1 and the gradient of the loss function being a negative number or in response to the pixel value being smaller than 0 and the gradient of the loss function being a positive number.

12. The apparatus of claim 10, wherein the determining the gradient of the activation function based on the pixel value of the modified mask image and the sign of the gradient of the loss function comprises determining the gradient of the activation function as 1 in response to the pixel value being greater than 1 and the gradient of the loss function being a positive number or in response to the pixel value being smaller than 0 and the gradient of the loss function being a negative number.

13. The apparatus of claim 10, wherein when determining the gradient of the activation function based on the pixel value of the modified mask image and the sign of the gradient of the loss function comprises determining the gradient of the activation function as 1 in response to the pixel value being greater than 0 and smaller than 1.

14. The apparatus of claim 10, wherein when determining the gradient of the activation function based on the pixel value of the modified mask image and the sign of the gradient of the loss function comprises determining the gradient of the activation function as 0 in response to the pixel value being greater than 1+m and the gradient of the loss function being a negative number or in response to the pixel value being smaller than 0−m and the gradient of the loss function being a positive number,
wherein the m is a real number greater than or equal to 0.

15. The apparatus of claim 10, wherein when determining the gradient of the activation function based on the pixel value of the modified mask image the sign of the gradient of the loss function comprises determining the gradient of the activation function as 1 in response to the pixel value being greater than 1+m and the gradient of the loss function being a positive number or in response to the pixel value being smaller than 0−m and the gradient of the loss function being a negative number,
wherein the m is a real number greater than or equal to 0.

16. The apparatus of claim 10, wherein when determining the gradient of the activation function based on the pixel value of the modified mask image and the sign of the gradient of the loss function comprises determining the gradient of the activation function as 1 in response to the pixel value being greater than 0−m and smaller than 1+m,
wherein the m is a real number greater than or equal to 0.

17. An apparatus for generating a mask image using an artificial intelligence (AI) model, the apparatus comprising:
one or more processors and a memory, wherein the memory stores instructions configured to cause the one or more processors to perform a process comprising:
receiving a gradient of a loss function, the loss function determined based on a difference between a target pattern and a pattern predicted from an image generated by the AI model based on the target pattern;
determining a gradient of an activation function based on a pixel value of the image and based on the gradient of the loss function;
updating the AI model based on the gradient of the activation function; and
generating the mask image using the updated AI model.

18. The apparatus of claim 17, wherein the determining the gradient of the activation function based on the pixel value of the image and the gradient of the loss function comprises
determining the gradient of the activation function as 0 in response to the pixel value being greater than 1 and the gradient of the loss function being a negative number or in response to the pixel value being smaller than 0 and the gradient of the loss function being a positive number.

19. The apparatus of claim 17, wherein the determining the gradient of the activation function based on the pixel value of the image and the gradient of the loss function comprises
determining the gradient of the activation function as 0 in response to the pixel value being greater than 1+m and the gradient of the loss function being a negative number in response to when the pixel value being smaller than 0−m and the gradient of the loss function being a positive number, wherein the m is a real number greater than or equal to 0.

20. The apparatus of claim 17, wherein the pattern is predicted by optical simulation in response to an image generated by the AI model being modified based on the activation function.
